(19) United States
(12) Patent Application Publication
(10) Pub. No.: US 2023/0208169 A1
(43) Pub. Date: Jun. 29, 2023

(54) Technique Using a Battery Charger and Battery Management System to Detect Cell Degradation and Pack Imminent Failures

(71) Applicant: Auto Motive Power Inc., Santa Fe Springs, CA (US)

(72) Inventors: Jiaqi LIANG, La Crescenta, CA (US); Moritz BOECKER, Millbrae, CA (US); William NORRIS, New York, NY (US); Anil PARYANI, Cerritos, CA (US); Garrett HEINEN, Long Beach, CA (US); Yousif KHAIREDDIN, Los Angeles, CA (US); Andrew ALMENDARES, Long Beach, CA (US); Michael HIBBARD, Long Beach, CA (US)

(21) Appl. No.: 18/091,289

(22) Filed: Dec. 29, 2022

Related U.S. Application Data
(60) Provisional application No. 63/294,727, filed on Dec. 29, 2021.

(51) Int. Cl. H02J 7/00; G01R 31/392; G01R 31/3842; G01R 31/389

(52) U.S. Cl. CPC H02J 7/0048; G01R 31/392; G01R 31/3842; G01R 31/389; H02J 7/00302; H02J 7/005

(57) ABSTRACT

An Energy Management Unit (EMU) integrates the on-board charger (OBC) and battery management system (BMS) and optional DC-DC to behave like a lab based Electrochemical Impedance Spectroscopy (EIS) device. New high-bandwidth charge control schemes, together with new high-voltage system architecture, are disclosed. During vehicle AC charging, the OBC outputs current that sweeps across various frequencies (typically 0.1 Hz to 10 kHz), while the BMS samples the voltage and current to create the Nyquist Plot (Real Vs Imaginary Impedance) of battery cell parameters, without high frequency cell voltage samples (which is not cost feasible for mobility and energy storage applications).

### FIELD

This relates to a Battery Management System (BMS) and Battery Charger in any application where high energy, and inherently unsafe, batteries cells are used.

### BACKGROUND

High-energy lithium battery cells have complex degradation modes and are inherently unsafe because internal short circuits will statistically occur. Cell short circuits are typically formed when the separator fails, allowing the positive and negative electrodes to come in contact. At that point, heat is generated, which typically leads to a thermal runaway event.

As described in papers, including “Reliable and Early Warning of Lithium Battery Thermal Runaway based on Electrochemical Impedance Spectrum” (Peng Dong et al 2021 J Electrochem. Soc 168 090529, “the Peng Dong article”), Electrochemical Impedance Spectroscopy (EIS) can be used as an analysis tool to detect early warnings and indications of pending safety issues, such as an imminent cell short. EIS lab equipment typically are current-mode controlled devices with very low output capacitance and high sampling rates, features that are cost prohibitive to live in mobility on-board chargers. The challenge is how to bring this EIS lab-based equipment to a vehicle level that is cost effective and reliable.

### SUMMARY

An Energy Management Unit (EMU) which combines a battery management system (BMS) and On-Board Charger (OBC) and Electric Drive System (EDS) for managing a battery is disclosed. The EMU includes a plurality of communications to Analog Front End (AFE) application-specific integrated circuit (ASICs) and current sensors, and a power-electronics assembly designed to take AC grid power and charge the battery.

### BRIEF DESCRIPTION OF THE DRAWINGS

FIGS. 1a and 1b illustrates exemplary high-voltage (HV) battery systems including on-board chargers, according to embodiments of the disclosure.

FIG. 2a illustrates an exemplary on-board charger and battery management system in communication with each other, according to an embodiment of the disclosure.

FIG. 2b illustrates another exemplary EMU with a battery management system distributed on three different processors, according to an embodiment of the disclosure.

FIG. 3 illustrates an exemplary output current waveform of an on-board charger, when injecting a sinusoidal current into a battery for EIS measurement, according to an embodiment of the disclosure.

FIG. 4 illustrates a typical Nyquist Plot of a lithium battery cell and typical 2RC battery model.

FIG. 5 illustrates low frequency voltage samples being stitched together if the fundamental frequency is known to create a Nyquist Plot of the bricks of cells, according to an embodiment of the disclosure.

FIG. 6 illustrates the exemplary steps in the operation of the OBC, according to an embodiment of the disclosure.

FIG. 7 illustrates a specific pulse test on a battery pack to extract the long depolarization time constants and mechanisms, according to an embodiment of the disclosure.

FIG. 8 displays enlarged image of the relaxation voltage, boxed region in FIG. 7, according to an embodiment of the disclosure.

### DETAILED DESCRIPTION

Various aspects of the novel systems, apparatuses, and methods are described more fully hereinafter with reference to the accompanying drawings. Aspects of this disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein, one skilled in the art should appreciate that the scope of the disclosure is Intended to cover any aspect of the novel systems, apparatuses, and methods disclosed herein, whether implemented independently of or combined with any other aspect. For example, an apparatus may be implemented or a method may be practiced using any number of the aspects set forth herein. In addition, the scope is intended to encompass such an apparatus or method which is practiced using other structure, functionality, or structure and functionality in addition to or other than the various aspects set forth herein. It should be understood that any aspect disclosed herein may be embodied by one or more elements of a claim.

Although particular aspects are described herein, many variations and permutations of these aspects fall within the scope of the disclosure. Although some benefits and advantages of the preferred aspects are mentioned, the scope of the disclosure is not intended to be limited to particular benefits, uses, or objectives. Rather, aspects of the disclosure are intended to be broadly applicable to e-mobility systems, including automotive, some of which are illustrated by way of example in the figures and in the following description of the preferred aspects. The detailed description and drawings are merely illustrative of the disclosure rather than limiting, the scope of the disclosure being defined by the appended claims and equivalents thereof.

Vehicle On-board chargers typically convert and isolate alternating current (AC) power to direct current (DC) battery power using a combination of capacitance and inductor energy storage devices as part of intermediate and output stages. As described in U.S. Pat. No. 1,458,856 entitled “Combined BMS, Charger, DC-DC in Electric Vehicles,” a charger can be engineered with very little capacitance in every power stage, including the output. Taking advantage of this low capacitance invention, new high-bandwidth charge control schemes, together with new high-voltage system architecture, can be realized to allow a vehicle charger to behave like a lab based Electrochemical Impedance Spectroscopy (EIS) or Frequency Response Analysis (FRA). During vehicle AC charging, the charger outputs current, that sweeps across various frequencies (typically, in the lab at 0.1 Hz to 10 kHz), into the high voltage (HV) battery, and the battery management system (BMS) measures the current and voltage responses from each cell and create the Nyquist Plot (Real Vs Imaginary Impedance) of battery cell parameters. The Peng Dong article describes how to use phase angle for early warning detection of shorted cells (thermal runaway). This is only one example of how to use an EIS for early warning detection of thermal runaway.

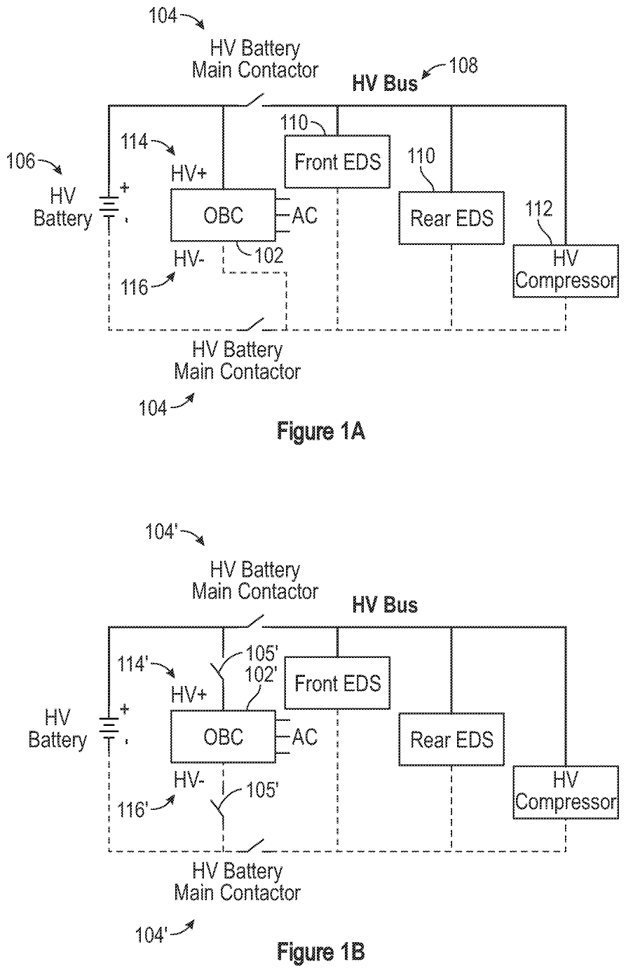

According to an embodiment of the present disclosure as illustrated in FIG. 1a, the on-board charger (OBC) 102 can be electrically connected to the battery side of the main HV battery contactors 104, to keep the bus capacitance low between the OBC 102 and HV battery 106. At high frequency (typically above a few hundred Hz), capacitors on the HV bus 108 can have lower impedance than the HV battery 106, and thus sinks most of the high frequency current injected by the OBC 102. Typically, the electric motor drive systems (EDS) 110 and HV compressor 112 on the vehicle HV bus 108 contribute to a large amount of bus capacitance. Keeping the HV battery main contactors 104 open can thus disconnect most of the HV bus capacitance and allows the OBC 102 to inject high frequency currents into the HV battery 106 without over-stressing the OBC 102. In the example of FIG. 1a, only one of the HV+ or HV− terminals 114, 116 of OBC 102 are connected to the battery side of the HV battery main contractors 104.

FIG. 1b illustrates an alternative embodiment of the new HV system architecture. In this embodiment, both the HV+ and HV− terminals 114′, 116′ of OBC 102′ are connected to the battery side of the HV battery main contactors 104′, through a single or pair of lower-rated contactors or solid state switches 105′. The latter embodiment is important to measure the battery impedance without the effect of bus capacitance.

According to embodiments of the present disclosure, once parameters are extracted from EIS and combined with battery impedance and open circuit voltage directly measured from the BMS, direct measurements of the State of Charge, State of Health and State of Power of a battery can be inferred. In addition, anomalies of frequency response can indicate a cell may be on the verge of runaway, while the DC response shows a normal behavior.

The Nyquist Theorem tells us that to properly recreate a waveform of a particular frequency, we need to theoretically sample at minimum two times of that frequency. But practically due to higher order noises, the sampling frequency usually needs to be several times (e.g., 10 times) higher. The challenge is that most Battery Management Systems (BMS) cannot sample cell voltages quickly enough as required by the EIS because the Analog Front End (AFE) application-specific integrated circuit ASICs used in BMSs struggle to obtain samples quicker than 10 msec, due to loop rate limit of typical isolated communication between BMS and AFEs, heavy filtering and precise A/D measurements needed for cell voltage inputs to battery algorithms, making it impossible to sample waveforms faster than 50 Hz (½*10 msec). However, due to the real-time digital control capability of modern digital power supplies, the frequency is known and can be communicated between the on-board charger (OBC) and BMS modules. Therefore, we can have a much lower sampling rate.

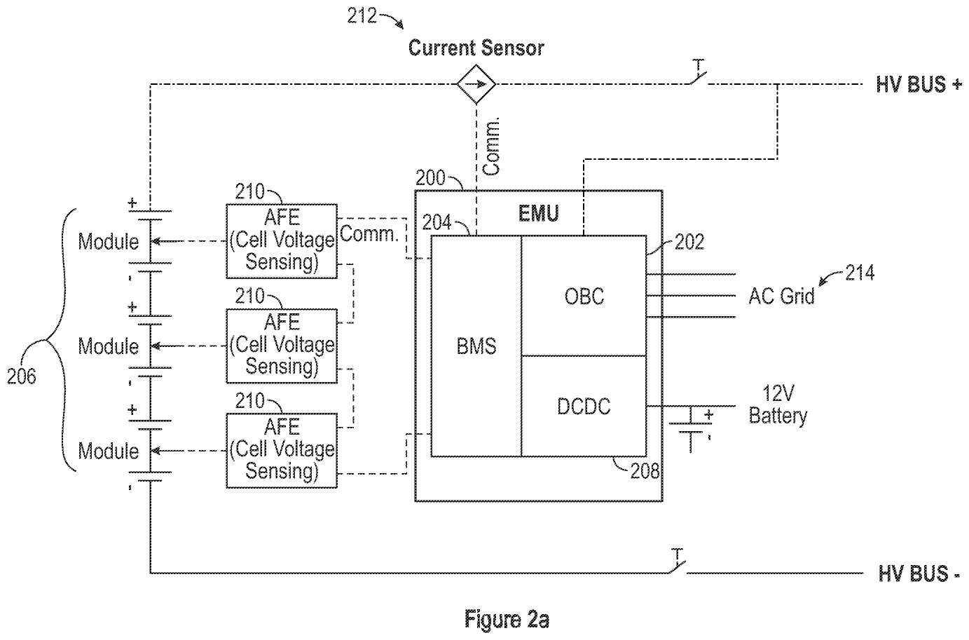

FIG. 2a illustrates an EMU 200 including an exemplary on-board charger 202 and battery management system 204 in communication with each other. Note that the OBC 202 and BMS 204 can be on the same physical controller or can be complete separated controllers, in which case, communication between the controllers can be via hardwired, CAN, I2C, SPI, SM-Bus, Serial, etc. If the BMS 202 and OBC 204 are software components in a combined system, then the frequency is already known. The EMU 200 can have a number of communications to Analog Front End (AFE) application-specific integrated circuit (ASICs) 210 and current sensors 212. In addition, the EMU 200 can include a power-electronics assembly designed to take AC grid power 214 and charge the battery 206.

FIG. 2b illustrates an embodiment in which the BMS 204′ is distributed as software components amongst 3 different processors (e.g., DC-DC 208′, OBC 202′, and iMX processor (or equivalent) 220). Isolated communications can be added to the MMBs 222, typically ISO-SPI and contactor/pyro fuse control with airbag input. This is because the OBC 202′ and DC-DC 208′ are monitoring the HV bus rails. The iMX 220 (or an equivalent processor) is designed to be a high compute processor with a lot of random access memory (RAM), which is needed to run advanced algorithms of high voltage packs when local compute regarding anomaly detection is performed. This is because each brick of cells in a battery pack needs to be controlled and quite a few parameters need to be stored. The embodiment illustrated in FIG. 2b can allow the BMS functions to be added to the EMU with very little cost.

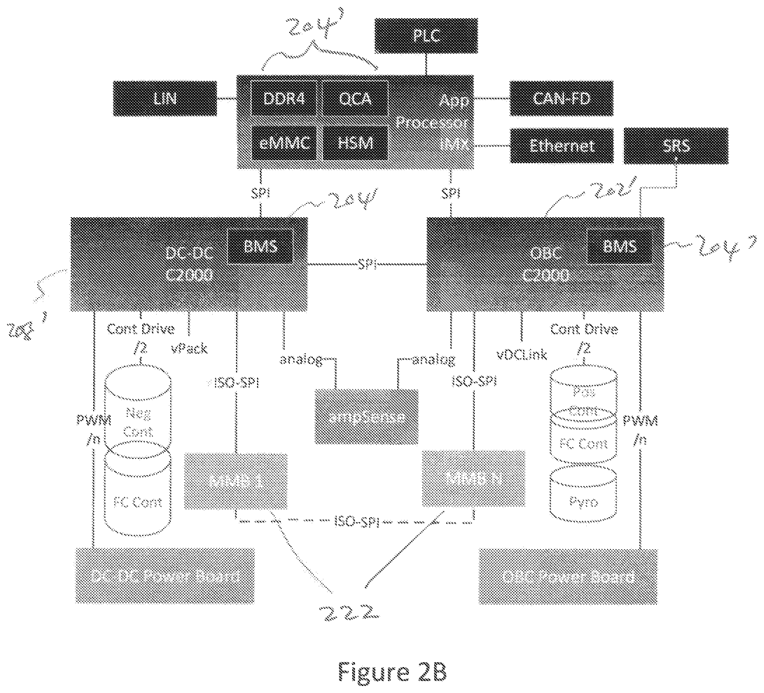

FIG. 3 illustrates an exemplary output current waveform 302 of an on-board charger (e.g., 202 of FIG. 2), when injecting a sinusoidal current into a battery (e.g., 206 of FIG. 2) for EIS measurement.

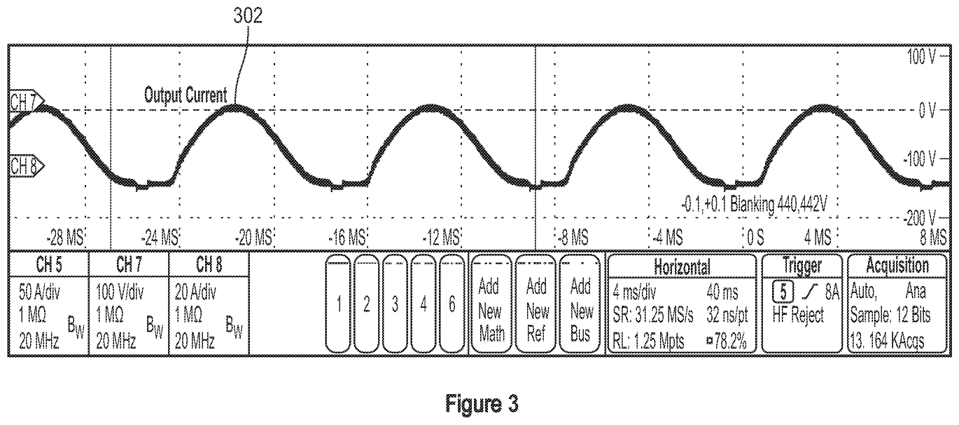

FIG. 4 illustrates a typical Nyquist Plot of a lithium battery cell and typical 2RC model.

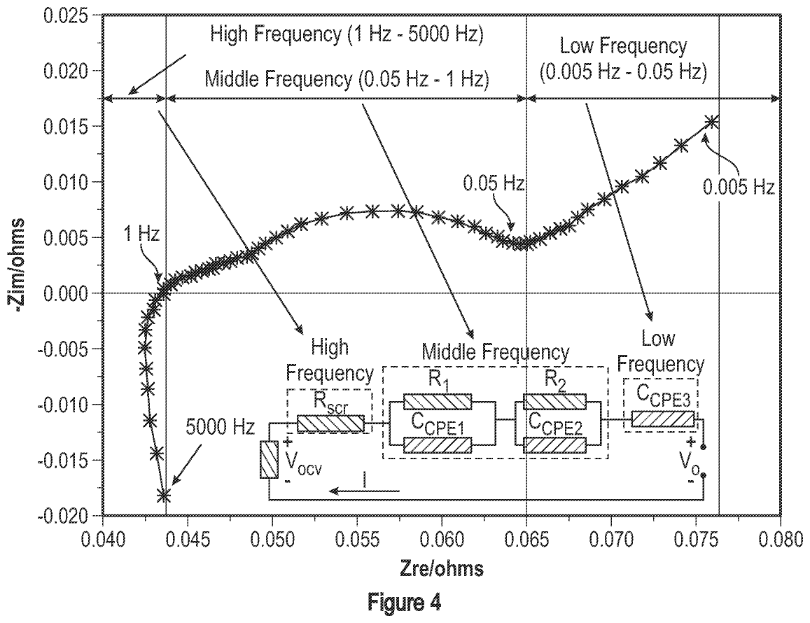

FIG. 5 illustrates low frequency voltage samples being stitched together if the fundamental frequency is known to create a Nyquist Plot of the bricks of cells (note 930 Hz used for illustration purposes). For example, if we are sampling 1 kHz signal with sampling rate of around 100 Hz (i.e., sampling period of around 10 msec), then after the first sample, the trigger point for the next samples will be slightly more than 10 msec, for example 10.1 msec. After stitching ten of the 10.1 msec samples together, we can achieve an effective sampling rate of 10 kHz for the 1 kHz signal. Note that a modern BMS has many techniques available to synchronize brick voltages and currents. In the embodiments of this disclosure, a shunt or high-speed Hall effect sensor can be used to accurately measure and synchronize the current to the cell or brick voltages for impedance estimation.

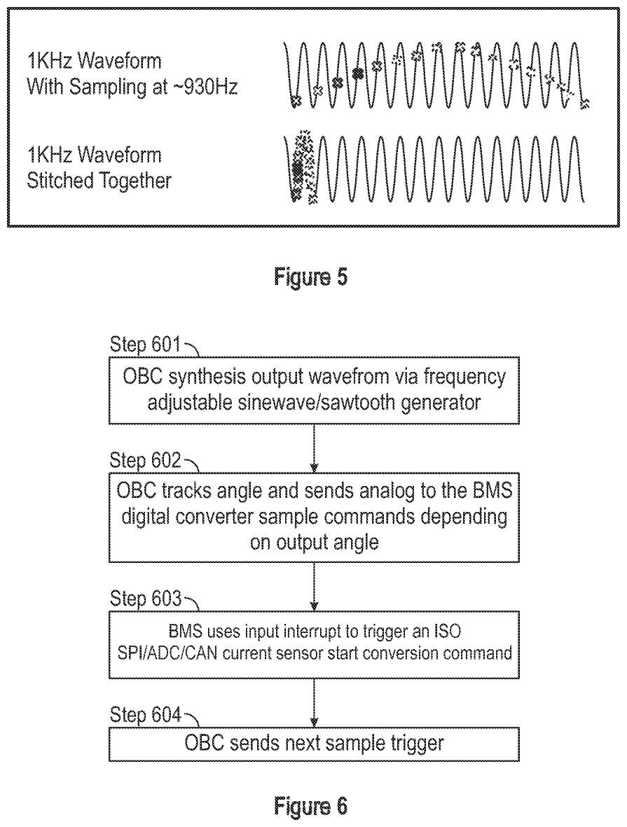

In one embodiment, as illustrated in FIG. 6, the OBC synthesizes an output waveform via frequency adjustable sine wave/sawtooth generator (+pulse for DC iR). (Step 601) The OBC internally tracks angle and sends analog to the BMS digital converter (ADC) sample commands depending on the corresponding output angle (0 to 2 pi). (Step 602) The OBC can trigger the BMS ADC sample request via a hardwired output/input interrupt (separate uCs)—or other internal trigger/interrupt mechanism if the BMS and OBC are in a combined system. The BMS will use the input interrupt to trigger isoSPI/CAN/ADC current sensor start of conversion command. (Step 603) After each ADC conversion is complete and BMS is ready, the OBC will send the next sample trigger theta(n)=theta(n−1)+d_theta. (Step 604) Note the ADC sample request must be for both the current measurement and all the cell voltage measurements, simultaneously, to accurately estimate the impedance.

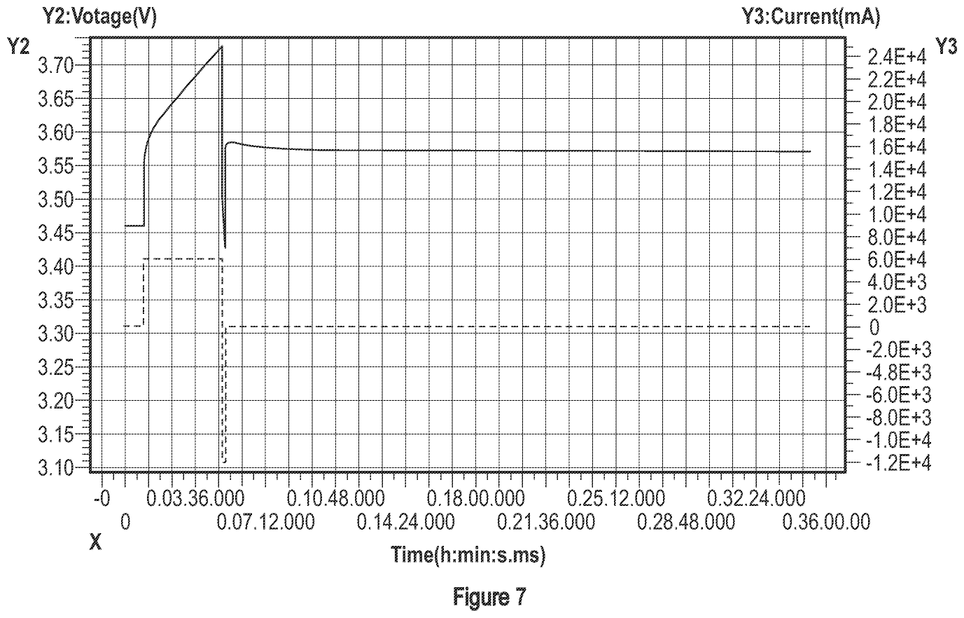

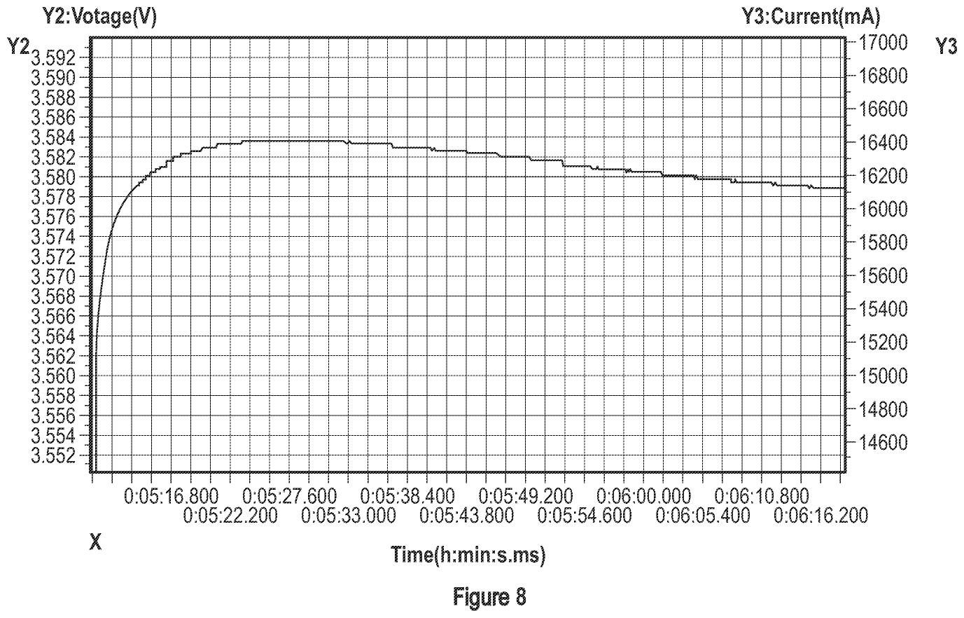

By controlling a BMS and Charger (e.g., OBC) in a combined system, another technique can be used in an addition to EIS. FIG. 7 illustrates a specific DC pulse test on a battery pack to extract the long depolarization time constants and mechanisms, according to an embodiment of the disclosure. FIG. 8 displays enlarged image of the relaxation voltage, boxed region in FIG. 7, according to an embodiment of the disclosure. These pulses can be introduced to a typical charge session, which will typically take anywhere between 1 hour and 12 hours and extend this charging time by minutes. The pulse test can complement the EIS test, to confirm battery model and parameter measurements and readings like power availability. But immediately, the power available is known by simply looking at a regression of dv/di. And then an action, like is it safe to drive, can be answered. This is extremely valuable in the case of cold charging.

To minimize data storage, the frequency sweep or pulse test can be periodically within a charge, perhaps at 10% state of charge (SOC) steps. To minimize the BMSs compute requirements, all signal processing and parameter extraction steps can be done on the charger or with the cloud.

Also, in a system, bus-bar/contactor/fuse impedance, and capacitance can be measured. If an anomaly is detected the appropriate action can be taken.

In another embodiment of this disclosure, the low voltage (typically 12V, 24V, or 48V) battery charger, e.g., a DC/DC converter 208 of FIG. 2 that converts power from HV battery 206 of FIG. 2 to charge the low voltage battery, can also inject current of various frequencies into the low voltage battery. In the same manner, the low voltage battery BMS can measure the current and voltage response of the battery cells and extracts the EIS battery parameters using the onboard low voltage battery charger. These EIS battery parameters can be used to diagnose degradation modes and imminent failure modes of the low voltage battery

Although embodiments of this disclosure have been fully described with reference to the accompanying drawings, it is to be noted that various changes and modifications will become apparent to those skilled in the art. Such changes and modifications are to be understood as being included within the scope of embodiments of this disclosure as defined by the appended claims.

What is claimed is:

1. An Energy Management Unit (EMU) which combines a battery management system (BMS) and On-Board Charger (OBC) and optional DC-DC for managing a battery comprising:
a plurality of communications to Analog Front End (AFE) application-specific integrated circuit (ASICs) and current sensors, and
a power-electronics assembly designed to take AC grid power and charge the battery.

2. The EMU of claim 1, wherein the OBC comprises a low output capacitance charger.

3. The EMU of claim 1, wherein one or both of DC outputs of the OBC are connected to a battery side of main contactors of the battery.

4. The EMU of claim 1, wherein only one DC output of the OBC is connected to a battery side of main contactors of the battery while maintaining functional safety against over-charge while being able to measure a battery frequency response without the signal being altered by a DC bus capacitance.

5. The EMU of claim 1, wherein the OBC is configured to control an output current at various sinusoidal frequencies.

6. The EMU of claim 1, when the OBC is configured to output current of various sinusoidal frequencies, when one or more of main contactors of the battery are in open state.

7. The EMU of claim 1, wherein the charger is configured to control DC pulses and directly measure the high voltage battery and/or low voltage battery power available.

8. The EMU of claim 1, wherein synchronized samples of battery current and voltage are acquired through the AFE ASICs and the current sensor, when the OBC is configured to output current of various sinusoidal frequencies.

9. The EMU of claim 1 further configured to compute battery impedance (magnitude and phase angle) of various frequencies, and re-create a Nyquist Plot data and parameters.

10. The combined EMU of claim 8, wherein the OBC is configured to synthesize an output waveform via frequency adjustable sine wave/sawtooth generator, internally track angle and send analog to digital converter (ADC) sample commands depending on a corresponding output angle.

11. The EMU of claim 1, wherein parameters are extracted to fit various battery models comprising 2RC model.

12. The EMU of claim 9 wherein the OBC is further configured to trigger a BMS ADC sample request via a hardwired output/input interrupt.

13. The EMU of claim 1, wherein parameters are extracted to indicate an imminent cell short failure, via phase angle analysis and cell anomaly

14. The EMU of claim 12, wherein the BMS is configured to use an input interrupt to trigger isoSPI/current sensor start of a conversion command; and
wherein, after each ADC conversion is complete and BMS is ready, the OBC is configured to send a next sample trigger theta(n)=theta(n−1)+d_theta.

15. The EMU of claim 1, wherein the OBC is configured to communicating to the BMS of its output current frequency

16. The EMU of claim 1, wherein voltages are sampled at a lower frequency and then stitched together to recreate a higher frequency signal.

17. The EMU of claim 1 further wherein the EMU allows improved measurements of State of Charge, State of Health and State of Power.

18. The EMU of claim 1 further comprising a low-voltage battery charger that converts power form a high-voltage battery and charge a low-voltage battery.

19. The EMU of claim 17, wherein the low-voltage battery charger comprises a DC/DC converter.

20. The EMU of claim 17, wherein the EMU allows current injection of various frequencies into the low-voltage battery, and extracts battery parameters to indicate an imminent cell short failure, via phase angle analysis.
